(19) United States
(12) Patent Application Publication
(10) Pub. No.: US 2022/0039255 A1
(43) Pub. Date: Feb. 3, 2022

(54) FLEXIBLE METAL LAMINATE AND PRINTED CIRCUIT BOARD USING THE SAME

(71) Applicant: DONGWOO FINE-CHEM CO., LTD., Iksan-si (KR)

(72) Inventors: Min Woo KIM, Pyeongtaek-si (KR); In Uk LEE, Gwangmyeong-si (KR); Inwon JUNG, Pyeongtaek-si (KR)

(73) Assignee: DONGWOO FINE-CHEM CO., LTD., Iksan-si (KR)

(21) Appl. No.: 17/386,772

(22) Filed: Jul. 28, 2021

(30) Foreign Application Priority Data
Jul. 31, 2020 (KR) 10-2020-0095702

(51) Int. Cl. H05K 1/03; B32B 27/28; B32B 15/08; B32B 15/20

(52) U.S. Cl. CPC H05K 1/0393; B32B 27/281; B32B 15/08; B32B 15/20; B32B 2307/204; B32B 2307/704; B32B 2255/10; B32B 2255/26; B32B 2307/732; B32B 2457/08; B32B 2307/546; B32B 2307/206

(57) ABSTRACT

A flexible metal laminate contains an insulation layer including a polyimide film, a first liquid crystal polymer coating layer formed on one surface of the polyimide film, and a second liquid crystal polymer coating layer formed on the other surface of the polyimide film, and a metal layer formed on at least one surface of the insulation layer. A printed circuit board containing the flexible metal laminate is also disclosed. The flexible metal laminate has an excellent dielectric property of the insulation layer, and the dielectric property of the insulation layer can be maintained excellently in a high temperature and high humidity environment to preserve high-speed, low-loss signal performance. Therefore, it can be advantageously applied to 5G communication products.

### CROSS REFERENCE TO RELATED APPLICATIONS

This application claims priority based on Korean Patent Application No. 10-2020-0095702, filed Jul. 31, 2020, the entire content of which is incorporated herein by reference in its entirety.

### TECHNICAL FIELD

The present invention relates to a flexible metal laminate and a printed circuit board using the same. Specifically, the present invention relates to a flexible metal laminate and a printed circuit board using the same that can preserve the high-speed, low-loss signal performance by maintaining excellent dielectric properties of an insulation layer in a high-temperature, high-humidity environment.

### BACKGROUND ART

Recently, communication and vehicle-mount markets are moving from 4G to 5G, and accordingly, high performance of various parts is required. In the case of 5G, the frequency from the existing 4G maximum 3.5 GHz to 5G maximum 28 GHz is required for communication, and the frequency up to 70 GHz is required for vehicle-mount use. Accordingly, low dielectric properties are required. Thus, various industries are developing materials for lowering dielectric properties.

Flexible metal laminates are mainly used as substrates for flexible printed circuit boards (FPCBs), and also used for surface heating element electromagnetic wave shielding materials, flat cables, packaging materials, and the like. Among these flexible metal laminates, a flexible copper foil laminate is mainly composed of a polyimide layer and a copper foil layer, which may be divided into an adhesive type and a non-adhesive type depending on whether an epoxy adhesive layer exists between the polyimide layer and the copper foil layer. In the non-adhesive type flexible copper foil laminate, the polyimide is directly adhered to a surface of the copper foil. Recently, in accordance with the trend of miniaturization and thinning of electronic products and demanding excellent ion migration characteristics, the non-adhesive type flexible copper foil laminates are mainly used.

Korean Patent Application Publication No. 10-2013-0027442 discloses a flexible metal laminate comprising a first metal layer; a first polyimide layer; a polyimide layer in which a fluororesin is dispersed formed on the first polyimide layer; and a second polyimide layer formed on the polyimide layer in which the fluororesin is dispersed, in which the content per unit volume of the fluororesin is greater at a depth of 40 to 60% than at a depth of 5 to 10% of the total thickness from the surface of the polyimide layer in the polyimide layer in which the fluororesin is dispersed, thereby improving adhesion to the metal layer and dielectric properties.

However, polyimide has a high water-absorption rate and thus poor moisture resistance, and accordingly, a dielectric characteristic is greatly deteriorated over time, which causes a problem that a signal loss rate is increased at a high frequency corresponding to 5G. In addition, polyimide itself has a high dielectric constant, so it is difficult to satisfy the high-speed level required recently.

In this regard, there is known a laminate in which a liquid crystal polymer (LCP) film and a metal layer capable of constituting a circuit (conductor pattern) are laminated.

This laminate has an advantage that a flexible printed circuit board can be formed by multilayering, and in that case, the high-density wiring is possible which yields a wide range of operation. However, there is a problem that the liquid crystal polymer film is not economical.

### DISCLOSURE OF INVENTION

### Technical Problem

An object of the present invention is to provide a flexible metal laminate capable of maintaining excellent dielectric properties of an insulation layer in a high-temperature, high-humidity environment, thereby preserving high-speed, low-loss signal performance.

Another object of the present invention is to provide a printed circuit board using the same flexible metal laminate.

### Technical Solution

An aspect of the present invention provides a flexible metal laminate comprising an insulation layer including a polyimide film, a first liquid crystal polymer coating layer formed on one surface of the polyimide film, and a second liquid crystal polymer coating layer formed on the other surface of the polyimide film, and a metal layer formed on at least one surface of the insulation layer.

The flexible metal laminate according to an embodiment of the present invention may satisfy Equation 1 below.

0.01≤(B+C)/A≤0.2 [Equation 1]

wherein,

A is a thickness of the polyimide film,

B is a thickness of the first liquid crystal polymer coating layer, and

C is a thickness of the second liquid crystal polymer coating layer.

In an embodiment of the present invention, the insulation layer may have a dielectric tangent change rate of 10% or less, defined by Equation 2 below:

Dielectric tangent change rate=[(D₂−D₁)/D₁]×100 [Equation 2]

wherein,

D₁ is an initial dielectric tangent (Df) value at a frequency of 10 GHz after maintaining the insulation layer at 23° C. and 50% relative humidity for 24 hours, and

D₂ is a dielectric tangent (Df) value at a frequency of 10 GHz after leaving the insulation layer at 85 V and 85% relative humidity for 240 hours.

In an embodiment of the present invention, a thickness of the polyimide film may be 10 to 100 μm.

In an embodiment of the present invention, the first and second liquid crystal polymer coating layers may be formed by coating a liquid crystal polymer composition on the polyimide film, drying at a temperature of 200° C. or less, and post-baking at a temperature of 250 to 300° C.

In an embodiment of the present invention, a thickness of each of the first and second liquid crystal polymer coating layers may be 0.1 to 10 μm.

In an embodiment of the present invention, the metal layer may comprise copper.

In an embodiment of the present invention, a thickness of the metal layer may be 1 to 20 μm.

Another aspect of the present invention provides a printed circuit board using the flexible metal laminate.

### Advantageous Effects

The flexible metal laminate according to the present invention includes an insulation layer having liquid crystal polymer coating layers formed on both sides of a polyimide film, so that the dielectric property of the insulation layer is excellent, and the dielectric property of the insulation layer can be maintained excellently in a high temperature and high humidity environment to preserve high-speed, low-loss signal performance. Therefore, the flexible metal laminate according to the present invention can maintain a low signal loss rate even in a high-temperature, high-humidity environment when applied to a flexible circuit board, and thus can be advantageously applied to 5G communication products.

### DESCRIPTION OF DRAWINGS

FIG. 1 is a structural cross-sectional view of a flexible metal laminate according to an embodiment of the present invention.

FIG. 2a and FIG. 2b are schematic diagrams illustrating a method of a flexibility test.

### BEST MODE

Hereinafter, the present invention will be described in detail.

One embodiment of the present invention relates to a flexible metal laminate comprising an insulation layer including a polyimide film and liquid crystal polymer coating layers formed on both surfaces thereof and a metal layer formed on at least one surface of the insulation layer.

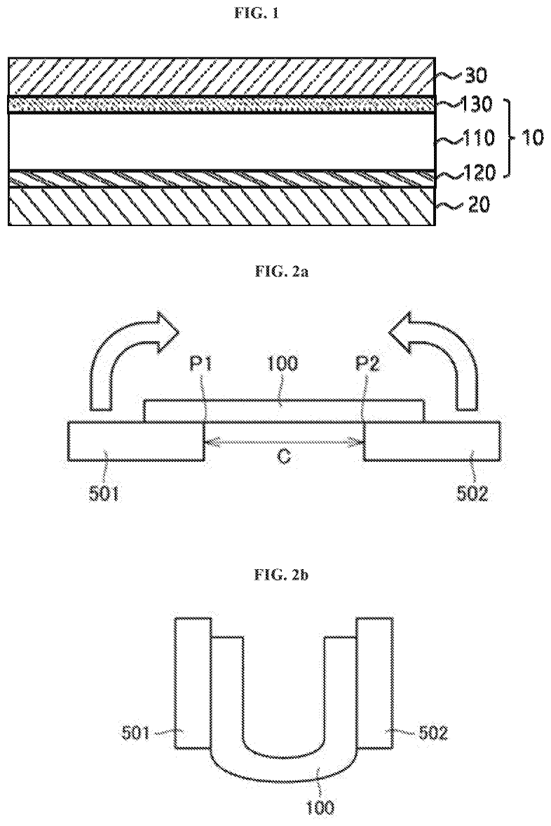

Referring to FIG. 1, a flexible metal laminate according to an embodiment of the present invention comprises an insulation layer 10 including a polyimide film 110, a first liquid crystal polymer coating layer 120 formed on one surface of the polyimide film, and a second liquid crystal polymer coating layer 130 formed on the other surface of the polyimide film, and a first metal layer 20 and a second metal layer 30 formed on both surfaces of the insulation layer. Although FIG. 1 shows that the first metal layer 20 and the second metal layer 30 are formed on both surfaces of the insulation layer, respectively, only one of the first metal layer 20 and the second metal layer 30 may be formed.

The flexible metal laminate according to an embodiment of the present invention includes the insulation layer having liquid crystal polymer coating layers formed on both sides of the polyimide film. Thus, the dielectric property of the insulation layer is better than that of the insulation layer having a polyimide film without liquid crystal polymer coating layers, and the dielectric property of the insulation layer can be maintained excellently in a high temperature and high humidity environment to preserve high-speed, low-loss signal performance.

The flexible metal laminate according to an embodiment of the present invention may satisfy Equation 1 below.

0.01≤(B+C)/A≤0.2 [Equation 1]

wherein,

A is a thickness of the polyimide film,

B is a thickness of the first liquid crystal polymer coating layer, and

C is a thickness of the second liquid crystal polymer coating layer.

The flexible metal laminate according to an embodiment of the present invention can maintain excellent dielectric properties of the insulation layer in a high-temperature, high-humidity environment by satisfying Equation 1 above. If the (B+C)/A value is less than 0.01, it may be difficult to maintain excellent dielectric properties of the insulation layer in a high-temperature, high-humidity environment. If it exceeds 0.2, the process cost may increase due to the increase in the number of coatings during the process, it may be difficult to reduce the thickness of the device, and the flexibility of the flexible metal laminate may be deteriorated.

In an embodiment of the present invention, the dielectric tangent change rate defined by the following Equation 2 of the insulation layer may be 10% or less.

Dielectric tangent change rate=[(D₂−D₁)/D₁]×100 [Equation 2]

wherein,

D₁ is an initial dielectric tangent (Df) value at a frequency of 10 GHz after maintaining the insulation layer at 23° C. and 50% relative humidity for 24 hours, and

D₂ is a dielectric tangent (Df) value at a frequency of 10 GHz after leaving the insulation layer at 85 V and 85% relative humidity for 240 hours.

The dielectric tangent is a unit representing a ratio of power loss generated when an AC voltage is applied to a dielectric, and it is generally expressed as tangent delta (tangent δ).

The dielectric tangent (Df) value is a value measured at a frequency of 10 GHz according to the method described in Experimental Examples to be described later with respect to the insulation layer.

The dielectric tangent change rate defined by Equation 2 of the insulation layer may be 10% or less, preferably 5% or less, as described above. If the dielectric tangent change rate of the insulation layer exceeds 10%, it may be difficult to preserve high-speed, low-loss signal performance when exposed to a high-temperature, high-humidity environment for a long time.

In an embodiment of the present invention, the polyimide film 110 serves as an insulation layer of the flexible metal laminate.

As the polyimide, a thermosetting polyimide produced by a dehydration condensation reaction according to heating of polyamic acid or a solvent-soluble polyimide of a non-dehydration condensation type may be used.

The thermosetting polyimide can be obtained by synthesis of a polyamic acid, which is an imide precursor, by reacting diamine and tetracarboxylic dianhydride in a polar solvent, and dehydration cyclization of the polyamic acid with heat, i.e. imidization.

As the diamine, aromatic diamines, alicyclic diamines, aliphatic diamines, and so on, which are commonly used for polyimide synthesis, may be used. These diamines can be used alone or in combination of two or more.

As the tetracarboxylic dianhydride, aromatic tetracarboxylic dianhydride, alicyclic tetracarboxylic dianhydride, aliphatic tetracarboxylic dianhydride, etc. can be used. These tetracarboxylic dianhydrides can be used alone or in combination of two or more.

In the case of producing a polyimide film using the thermosetting polyimide, a composition containing polyamic acid is applied on a substrate to form a coating film, dried and heat-treated for imidization to prepare a polyimide film. At this time, as the coating method, a spray method, a roll coating method, a rotary coating method, a bar coating method, an inkjet method, a screen printing method, a slit coating method and the like may be used. The drying may be performed at a temperature of 140° C. or less, and the heat treatment may be performed at a temperature of 200 to 600° C.

Since the solvent-soluble polyimide is already iridized and soluble in a solvent, it can be prepared in the form of a coating solution dissolved in a solvent, applied on a substrate, and dried to form a film. As the coating method, a spray method, a roll coating method, a rotary coating method, a bar coating method, an inkjet method, a screen printing method, a slit coating method, and the like may be used. The drying may be performed at a temperature of less than 200° C.

The thickness of the polyimide film 110 may be 10 to 100 μm, preferably 10 to 50 μm. If the thickness of the polyimide film 110 is less than 10 μm, the film thickness uniformity of the liquid crystal polymer coating layer may not be constant. If it exceeds 100 μm, the effect of improving properties as the thickness increases may no longer be obtained or flexibility may be reduced.

In an embodiment of the present invention, the first and second liquid crystal polymer coating layers 120 and 130 are respectively formed on both surfaces of the polyimide film 110 to play a role in improving dielectric properties and moisture resistance of the polyimide film 110.

The first and second liquid crystal polymer coating layers 120 and 130 are coating films formed by coating and drying a liquid liquid crystal polymer composition.

The first and second liquid crystal polymer coating layers 120 and 130 may be formed by applying a liquid crystal polymer composition on the surface of the polyimide film, drying at a temperature of 200° C. or less, for example, 100 to 200° C., preferably 120 to 150° C., and post-baking at a temperature of 250 to 300° C.

The liquid crystal polymer composition is a liquid crystal polymer dispersed in a solvent.

The liquid crystal polymer refers to a thermoplastic plastic exhibiting nematic crystallinity upon melting.

As the liquid crystal polymer, those used in the art may be used without particular limitation, and may preferably be liquid crystalline polyester.

The liquid crystalline polyester may be a liquid crystalline polyester amide, a liquid crystalline polyester ether, a liquid crystalline polyester carbonate, liquid crystalline polyester imide, or the like. The liquid crystalline polyester is preferably a fully aromatic liquid crystalline polyester formed by using only an aromatic compound as a raw material monomer.

Preferably, the liquid crystalline polyester may include, for example, at least one of a repeating unit derived from an aromatic diamine, a repeating unit derived from an aromatic amine having a hydroxyl group, or a repeating unit derived from an aromatic amino acid.

When the liquid crystalline polyester includes the above repeating units, it may be included in an amount of 10 to 35 mol % based on 100 mol % of all repeating units constituting the liquid crystalline polyester. This may mean that when the liquid crystalline polyester includes two or more kinds of the repeating units, the total mol % of the two or more kinds of repeating units is 10 to 35 mol %.

More preferably, the liquid crystalline polyester may include a repeating unit derived from an aromatic hydroxycarboxylic acid, a repeating unit derived from an aromatic dicarboxylic acid, and a repeating unit derived from an aromatic diamine, an aromatic amine having a hydroxyl group or an aromatic amino acid. For example, the liquid crystalline polyester may include repeating units represented by the following Chemical Formulae 1 to 3, and their contents may be 30 to 80 mol %, 10 to 35 mol %, and 10 to 35 mol %, respectively, based on 100 mol % of all repeating units constituting the liquid crystalline polyester.

—O—Ar₁—CO— [Chemical Formula 1]

(In the above Chemical Formula 1,

Ar₁ is 1,4-phenylene, 2,6-naphthalene or 4,4′-biphenylene)

—CO—Ar₂—CO— [Chemical Formula 2]

(In the above Chemical Formula 2,

Are is 1,4-phenylene, 1,3-phenylene or 2,6-naphthalene)

—X—Ar₃—Y— [Chemical Formula 3]

(In the above Chemical Formula 3,

X is NH,

Y is O, NH or C═O, and

Ar₃ is 1,4-phenylene or 1,3-phenylene.)

In place of the aromatic hydroxycarboxylic acid, aromatic dicarboxylic acid, aromatic diamine, aromatic amine having a hydroxyl group or aromatic amino acid, the liquid crystalline polyester including the above repeating units may be produced by using ester formable derivatives thereof such as derivatives having ester forming property, but it is not limited thereto.

The ester formable derivatives of a compound having a carboxylic acid group may include, for example, those in which the carboxyl group is present in the form of an acid chloride, an acid anhydride and the like so as to promote polyester formation reaction with high reactivity, or those in which the carboxyl group forms an ester with alcohols, ethylene glycol and the like so that a polyester is formed by a transesterification reaction.

The ester formable derivatives of a compound having an aromatic hydroxyl group may include, for example, those in which the aromatic hydroxyl group forms an ester with carboxylic acids so that a polyester is formed by a transesterification reaction.

Examples of the ester formable derivatives of a compound having an amino group may include, for example, those in which the amino group forms an ester with carboxylic acids so that a polyester is formed by a transesterification reaction.

Examples of the repeating unit represent by Chemical Formula 1 include repeating units derived from at least one selected from the group consisting of p-hydroxybenzoic acid, 2-hydroxy-6-naphthoic acid, 4-hydroxy-4′-biphenylcarboxylic acid, and 6-hydroxy-2-naphthalenecarboxylic acid.

The content of the repeating unit represent by Chemical Formula 1 may be 30 to 80 mol %, preferably 40 to 70 mol %, and more preferably 45 to 65 mol %, based on 100 mol % of the total repeating units constituting the liquid crystalline polyester including the same, but it is not limited thereto. If it exceeds the above range, solubility in a solvent may decrease. If included below the above range, liquid crystallinity may not be exhibited.

Examples of the repeating unit represented by Chemical Formula 2 include repeating units derived from at least one selected from the group consisting of terephthalic acid, isophthalic acid, 2,6-naphthalene dicarboxylic acid, and 1,3-benzenedicarboxylic acid.

The content of the repeating unit represent by Chemical Formula 2 may be 10 to 35 mol %, preferably 15 to 30 mol %, and more preferably 17.5 to 27.5 mol %, based on 100 mol % of the total repeating units constituting the liquid crystalline polyester including the same, but it is not limited thereto. If the above content is satisfied, solubility in a solvent may be further improved.

Examples of the repeating unit represented by Chemical Formula 3 include repeating units derived from at least one selected from the group consisting of 3-aminophenol, 4-aminophenol, 1,4-phenylenediamine, and 1,3-phenylenediamine.

The content of the repeating unit represent by Chemical Formula 3 may be 10 to 35 mol %, preferably 15 to 30 mol %, and more preferably 17.5 to 27.5 mol %, based on 100 mol % of the total repeating units constituting the liquid crystalline polyester including the same, but it is not limited thereto. If it exceeds the above range, liquid crystallinity may be reduced. If included below the above range, solubility in a solvent may be somewhat reduced.

The liquid crystal polymer may be included in an amount of 5 to 30 wt %, preferably 5 to 20 wt %, and more preferably 5 to 15 wt %, based on 100 wt % of the composition.

If the content of the liquid crystal polymer is included below the above range, problems in processability such as the composition flowing down during coating of the composition including the same may occur. If it exceeds the above range, there may be a problem that it is somewhat difficult to control the thickness during coating due to the increase of the viscosity.

In an embodiment of the present invention, the solvent serves as a dispersion medium for the liquid crystal polymer, and may be an aprotic solvent.

Examples of the aprotic solvent include: halogen solvents such as 1-chlorobutane, chlorobenzene, 1,1-dichloroethane, 1,2-dichloroethane, chloroform and 1,1,2,2-tetrachloroethane; ether solvents such as diethyl ether, tetrahydrofuran and 1,4-dioxane; ketone solvents such as acetone and cyclohexanone; ester solvents such as ethyl acetate; lactone solvents such as γ-butyrolactone; carbonate solvents such as ethylene carbonate and propylene carbonate; amine solvents such as triethylamine and pyridine; nitrile solvents such as acetonitrile and succinonitrile; amide solvents such as N,N′-dimethyl formamide, N,N′-dimethyl acetoamide, tetramethylurea and N-methylpyrrolidone; nitro solvents such as nitromethane and nitrobenzene; sulfide solvents such as dimethylsulfoxide and sulfolane; and phosphate solvents such as hexamethylphosphoramide and tri-n-butylphosphate.

Among the above solvents, solvents free from halogen atoms are preferably used in consideration of the influence on the environment, and solvents having a dipole moment of 3 to 5 are preferably used from the viewpoint of the solubility. Solvent having a dipole moment of 3 to 5 include amide solvents such as N,N′-dimethyl formamide, N,N′-dimethyl acetoamide, tetramethylurea and N-methylpyrrolidone and lactone solvents such as γ-butyrolactone, and preferably N,N′-dimethyl formamide, N,N′-dimethyl acetoamide and N-methylpyrrolidone, but they are not limited thereto.

In the liquid crystal polymer composition, if necessary, additives such as other thermoplastic resins, surfactants, coupling agents, anti-settling agents, UV absorbers, heat stabilizers, antioxidants, antistatic agents, flame retardants, and colorants may be used in combination.

Examples of the other thermoplastic resins include polypropylene, polyamide, polyphenylene sulfide, polyether ketone, polycarbonate, polyether sulfone, polyphenyl ether and modified polymers thereof, and polyether imide, and an elastomer such as a copolymer of glycidyl methacrylate and ethylene, but they are is not limited thereto.

Each of the first and second liquid crystal polymer coating layers 120 and 130 may have a thickness of 0.1 to 10 λm, preferably 1 to 5 μm. If the thickness of each of the first and second liquid crystal polymer coating layers 120 and 130 is less than 0.1 μm, the effect of improving moisture resistance may be reduced. If it exceeds 10 μm, the number of coatings in the process may increase, thereby increasing the process cost. In addition, it may be difficult to reduce the thickness of the device, and the flexibility of the flexible metal laminate may be poor.

In an embodiment of the present invention, the first metal layer 20 and the second metal layer 30 may include one or more metals selected from the group consisting of copper, iron, nickel, titanium, aluminum, silver, gold, palladium, chromium, molybdenum, and tungsten. Preferably, the first metal layer 20 and the second metal layer 30 may be a copper foil including copper having excellent electrical conductivity and low price, but it is not limited thereto.

The first metal layer 20 and the second metal layer 30 may be a layer formed by electrolysis or a layer formed by rolling.

Each of the first metal layer 20 and the second metal layer 30 may have a thickness of 1 to 20 λm, preferably 5 to 13 λm. If the thickness of each of the first metal layer 20 and the second metal layer 30 is within the above range, the tension of the metal layer can be easily adjusted during the production of the flexible metal laminate and the obtained flexible metal laminate may have excellent flexibility. If the thickness of each of the first metal layer 20 and the second metal layer 30 is less than 1 μm, handling may be difficult during the process and the unit price of the material may increase. If it exceeds 20 m, thinning may be difficult and flexibility may be lowered.

One embodiment of the present invention relates to a method of manufacturing the flexible metal laminate.

The method of manufacturing a flexible metal laminate according to an embodiment of the present invention comprises:

forming first and second liquid crystal polymer coating layers on both sides of a polyimide film to obtain an insulation layer; and

bonding a metal layer to at least one surface of the insulation layer.

In an embodiment of the present invention, the first and second liquid crystal polymer coating layers may be formed by applying a liquid crystal polymer composition on a polyimide film and drying at a temperature of 200° C. or less, for example 100 to 200, preferably 120 to 150° C., followed by a post-baking at a temperature of 250 to 300° C.

The post-baking may be performed by raising the temperature from 20 to 40° C. to 250 to 300° C., preferably 270 to 290° C. for 120 to 360 minutes, and then maintaining the elevated temperature for 60 to 240 minutes.

Components, thicknesses, dielectric tangents, and the like of the polyimide film and the first and second liquid crystal polymer coating layers are the same as described in the flexible metal laminate.

Components, thickness, and the like of the metal layer are the same as described in the flexible metal laminate.

The insulation layer and the metal layer may be bonded by a thermal fusion method, but if necessary, an adhesive or pressure sensitive adhesive layer may be further included for bonding each layer.

The thermal fusion may be performed using a heating roll, a double belt press, a heating plate, or a combination thereof.

The bonding temperature may be Tm±40° C. (Tm is a melting point of the liquid crystal polymer), preferably Tm±20° C. If the bonding temperature is less than Tm−40° C., the melting of the surface of the insulation layer is weak, and the anchoring effect to the metal layer is reduced. Thus, the adhesion to the metal layer may be reduced. If it exceeds Tm+40° C., the melting of the insulation layer is intensified and an overflow phenomenon may occur.

The bonding pressure may be 3 to 15 MPa, preferably 6 to 12 MPa. If the bonding pressure is less than 3 MPa, the pressurization of the metal layer and the insulation layer may not be sufficient, so that the adhesion may be reduced. If it exceeds 15 MPa, cracks may occur inside the insulation layer due to overpressure, and mechanical properties may be deteriorated.

The melting point of the liquid crystal polymer may be slightly different depending on the types and contents of the constituent repeating units, but may be approximately 260 to 350° C.

The bonding time may be 1 to 15 minutes, preferably 3 to 12 minutes. If the bonding time is less than 1 minute, the pressurization of the metal layer and the insulation layer may not be sufficient, so that the adhesion may be reduced. If it exceeds 15 minutes, the productivity may be reduced by increasing the process time.

One embodiment of the present invention relates to a printed circuit board using the flexible metal laminate.

The printed circuit board may be manufactured by forming a circuit pattern on at least one metal layer of the flexible metal laminate through etching or the like.

The printed circuit board may be a flexible printed circuit board.

Hereinafter, the present invention will be described in more detail by way of Examples, Comparative Examples and Experimental Examples. These Examples, Comparative Examples, and Experimental Examples are only for illustrating the present invention, and it is apparent to those skilled in the art that the scope of the present invention is not limited thereto.

### Preparation Examples 1 to 7: Preparation of Insulation Layer Comprising Liquid Crystal Polymer Coating Layers

A liquid crystal polymer composition (a copolymer of 1,3-benzenedicarboxylic acid, 4-aminophenol and 6-hydroxy-2-naphthalenecarboxylic acid, solid content 8 wt %, NMP solvent 92%, manufactured by SCC) was applied on one side of a polyimide film (SK, GF Sense), and then dried at 130° C. for 15 minutes to form a first liquid crystal polymer coating layer. After forming a second liquid crystal polymer coating layer on the other side of the polyimide film in the same manner, the temperature was raised from 30° C. to 290° C. for 240 minutes, and then the temperature of 290° C. was maintained for 120 minutes to perform post-baking to obtain an insulation layer.

At this time, the thicknesses of the polyimide film and the first and second liquid crystal polymer coating layers were controlled as described in Table 1 below.

### Preparation Comparative Example 1: Preparation of Polyimide Film Insulation Layer

A polyimide film (SK, GF Series) was prepared as a single-layer insulation layer.

### Experimental Example 1: Dielectric Properties of Insulation Layers

The dielectric properties of the insulation layers of the Preparation Examples and Preparation Comparative Examples were measured as follows before and after leaving them under a high-temperature, high-humidity environment, and the results are shown in Table 1.

After maintaining the insulation layers including the liquid crystal polymer coating layers of Preparation Examples 1 to 7 or the polyimide film insulation layer of Preparation Comparative Example 1 at a temperature of 23° C. and a relative humidity of 50% for 24 hours, the initial dielectric constant (Dk) and dielectric tangent (Df) values were measured at a frequency of 10 GHz using a dielectric constant measuring device (Anritsu Co., Ltd., product name MS46522B).

Thereafter, the insulation layers were left at 85° C. and 85% relative humidity for 240 hours, and then the dielectric constant (Dk) and the dielectric tangent (Df) values at a frequency of 10 GHz were measured.

The dielectric constant (Dk) and dielectric tangent (Df) values were measured at a frequency of 10 GHz by cutting the insulation layer to a size of 30 mm in length×70 mm in width to prepare a sample, and then inserting the sample into a probe of the measuring device.

The dielectric tangent change rate defined by Equation 2 below for the insulation layer was calculated and shown in Table 1.

Dielectric tangent change rate=[(D₂−D₁)/D₁]×100 [Equation 2]

wherein,

D₁ is an initial dielectric tangent (Df) value at a frequency of 10 GHz after maintaining the insulation layer at 23° C. and 50% relative humidity for 24 hours, and

D₂ is a dielectric tangent (Df) value at a frequency of 10 GHz after leaving the insulation layer at 85° C. and 85% relative humidity for 240 hours.

TABLE 1

| | | | | | | | Dielectric tangent (Df) | | |
|---|---|---|---|---|---|---|---|---|---|
| | | | | | Dielectric | | | | Dielectric |
| | Thickness | | | | constant (Dk) | | Initial | 85° C., | tangent |
| | A | B | C | (B + | Initial | 85° C., | value | 85RH % | change |
| | (μm) | (μm) | (μm) | C)/A | value | 85RH % | (D₁) | (D₂) | rate (%) |
| Preparation | 50 | 2 | 2 | 0.08 | 3.25 | 3.31 | 0.0102 | 0.0103 | 0.98 |
| Example 1 | | | | | | | | | |
| Preparation | 50 | 2.5 | 2.5 | 0.1 | 3.25 | 3.32 | 0.0103 | 0.0105 | 1.94 |
| Example 2 | | | | | | | | | |
| Preparation | 50 | 5 | 5 | 0.2 | 3.25 | 3.30 | 0.0096 | 0.0098 | 2.08 |
| Example 3 | | | | | | | | | |
| Preparation | 50 | 1 | 1 | 0.04 | 3.26 | 3.33 | 0.0103 | 0.0104 | 0.97 |
| Example 4 | | | | | | | | | |
| Preparation | 100 | 5 | 5 | 0.1 | 3.25 | 3.31 | 0.0095 | 0.0096 | 1.05 |
| Example 5 | | | | | | | | | |
| Preparation | 25 | 1 | 1 | 0.08 | 3.26 | 3.32 | 0.0102 | 0.0105 | 2.94 |
| Example 6 | | | | | | | | | |
| Preparation | 50 | 2 | 1 | 0.06 | 3.27 | 3.33 | 0.0103 | 0.0104 | 0.97 |
| Example 7 | | | | | | | | | |
| Preparation | 50 | 0 | 0 | 0 | 3.27 | 3.61 | 0.0122 | 0.0162 | 32.8 |
| Comparative | | | | | | | | | |
| Example 1 | | | | | | | | | |

A: Thickness of polyimide film

B: Thickness of the first liquid crystal polymer coating layer

C: Thickness of the second liquid crystal polymer coating layer

D₁: Initial dielectric tangent (Df) value at a frequency of 10 GHz after maintaining the insulation layer at 23 V and 50% relative humidity for 24 hours

D₂: Dielectric tangent (Df) value at a frequency of 10 GHz after leaving the insulation layer at 85 V and 85% relative humidity for 240 hours

As shown in Table 1, the insulation layers of Preparation Examples 1 to 7, in which the liquid crystal polymer coating layers were formed on both sides of the polyimide film exhibited lower dielectric properties, as compared to the polyimide film of Preparation Comparative Example 1 in which the liquid crystal polymer coating layer is not formed. Even after being left in a high-temperature, high-humidity environment, the dielectric tangent change rate was less than 10%, confirming that the lower dielectric properties were well maintained.

### Example 1: Preparation of Flexible Metal Laminate

After laminating copper foil substrates (thickness 12 μm, manufacturer Mitsui, product name SP-2) on the upper and lower surfaces of the insulation layer prepared in Preparation Example 1, it was put into a vacuum press (Kitagawa Seiki, Model-KVHC). A flexible metal laminate was prepared by pressurizing at a temperature of 290° C. (temperature rising 60 minutes, holding 5 minutes, temperature lowering 60 minutes), a surface pressure of 9 MPa, and a vacuum degree of 0.1 kPa.

### Example 2: Preparation of Flexible Metal Laminate

A flexible metal laminate was manufactured in the same manner as in Example 1, except that the insulation layer prepared in Preparation Example 2 was used instead of the insulation layer prepared in Preparation Example 1.

### Example 3: Preparation of Flexible Metal Laminate

A flexible metal laminate was manufactured in the same manner as in Example 1, except that the insulation layer prepared in Preparation Example 3 was used instead of the insulation layer prepared in Preparation Example 1.

### Example 4: Preparation of Flexible Metal Laminate

A flexible metal laminate was manufactured in the same manner as in Example 1, except that the insulation layer prepared in Preparation Example 4 was used instead of the insulation layer prepared in Preparation Example 1.

### Example 5: Preparation of Flexible Metal Laminate

A flexible metal laminate was manufactured in the same manner as in Example 1, except that the insulation layer prepared in Preparation Example 5 was used instead of the insulation layer prepared in Preparation Example 1.

### Example 6: Preparation of Flexible Metal Laminate

A flexible metal laminate was manufactured in the same manner as in Example 1, except that the insulation layer prepared in Preparation Example 6 was used instead of the insulation layer prepared in Preparation Example 1.

### Example 7: Preparation of Flexible Metal Laminate

A flexible metal laminate was manufactured in the same manner as in Example 1, except that the insulation layer prepared in Preparation Example 7 was used instead of the insulation layer prepared in Preparation Example 1.

### Comparative Example 1: Preparation of Flexible Metal Laminate

A flexible metal laminate was manufactured in the same manner as in Example 1, except that the insulation layer prepared in Preparation Comparative Example 1 was used instead of the insulation layer prepared in Preparation Example 1.

### Experimental Example 2: Evaluation of Physical Properties of Flexible Metal Laminates

The bending resistance (flexibility) of the flexible metal laminates prepared in Examples and Comparative Examples were measured in the MD and TD directions as follows, and the results are shown in Table 2. At this time, the MD direction refers to a direction in which the laminated body proceeds during the manufacturing process of the laminate, and the TD direction refers to a direction perpendicular to the MD direction.

The flexible metal laminate was subjected to a flexibility test as shown in FIGS. 2a and 2b.

A bending device (┌STS-VRT-500┘ manufactured by Science Town) having two stages 501 and 502 was prepared, and the flexible metal laminate 100 was placed on the stages 501 and 502 with the first metal layer 20 facing the opposite side of the stage (FIG. 2a). The distance (gap) C between the two stages 501 and 502 was set to 2 mm (1.0R). The stages 501 and 502 are swingable centering on the space (gap) C between the two stages, and the two stages 501 and 502 initially form the same plane. The two stages 501 and 502 are rotated upward 90 degrees with the positions P1 and P2 as the center of the rotation axis to fold the two stages 501 and 502 (FIG. 2b), and then the stages 501 and 502 are unfolded again. This movement is defined as one bending. According to the following criteria, the number of bending until cracks occurred was shown in Table 2 below as the number of bending resistance.

Crack occurrence criteria: resistance measurement after visual check
Visual check: When a crack is estimated by visual check of the bending portion, stop folding
Resistance measurement: After visual check, it is regarded as a crack when the resistance value rises or when a short circuit occurs through resistance measurement confirmation (The basic resistance of copper foil is 0.3 ohms. When a crack occurs, it is increased to 0.5 ohm or more. The resistance cannot be measured in case of short circuit.)

Count the number of bending until the occurrence of cracks

TABLE 2

| | Number of bending resistance (times) |
|---|---|
| Example 1 | 324 (MD), 325 (TD) |
| Example 2 | 316 (MD), 321 (TD) |
| Example 3 | 259 (MD), 252 (TD) |
| Example 4 | 321 (MD), 322 (TD) |
| Example 5 | 224 (MD), 225 (TD) |
| Example 6 | 327 (MD), 329 (TD) |
| Example 7 | 328 (MD), 323 (TD) |
| Comparative Example 1 | 330 (MD), 334 (TD) |

As shown in Table 2 above, the flexible metal laminates of Examples 1 to 7 including the insulation layer of Preparation Examples 1 to 7 satisfying the following Equation 1 as an insulation layer, in which liquid crystal polymer coating layers are formed on both sides of the polyimide film, showed the same level of flexibility even if the thickness was further increased, as compared to the flexible metal laminate of Comparative Example 1 including the polyimide film of Preparation Comparative Example 1 without forming liquid crystal polymer coating layers.

0.01≤(B+C)/A≤0.2 [Equation 1]

wherein,

A is a thickness of the polyimide film,

B is a thickness of the first liquid crystal polymer coating layer, and

C is a thickness of the second liquid crystal polymer coating layer.

The preferred embodiments of the present invention have been described with reference to the drawings. However, the present invention is not limited to the above-described embodiments, and it will be understood that the present invention can be implemented in a modified form without departing from the essential characteristics of the present invention.

Therefore, the scope of the present invention is defined by the claims rather than the foregoing description, and all differences within the equivalent range should be interpreted as being included in the present invention.

### DESCRIPTION OF REFERENCE NUMERALS

10: insulation layer
20: first metal layer
30: second metal layer
110: polyimide film
120: first liquid crystal polymer coating layer
130: second liquid crystal polymer coating layer
100: flexible metal laminate
501, 502: stages of bending device

1. A flexible metal laminate comprising:
an insulation layer including a polyimide film, a first liquid crystal polymer coating layer formed on one surface of the polyimide film, and a second liquid crystal polymer coating layer formed on the other surface of the polyimide film; and
a metal layer formed on at least one surface of the insulation layer.

2. The flexible metal laminate according to claim 1, satisfying Equation 1 below:
0.01≤(B+C)/A≤0.2 [Equation 1]
wherein,
A is a thickness of the polyimide film,
B is a thickness of the first liquid crystal polymer coating layer, and
C is a thickness of the second liquid crystal polymer coating layer.

3. The flexible metal laminate according to claim 1, wherein the insulation layer has a dielectric tangent change rate of 10% or less, defined by Equation 2 below:
Dielectric tangent change rate=[(D₂−D₁)/D₁]×100 [Equation 2]
wherein,
D₁ is an initial dielectric tangent (Df) value at a frequency of 10 GHz after maintaining the insulation layer at 23 V and 50% relative humidity for 24 hours, and
D₂ is a dielectric tangent (Df) value at a frequency of 10 GHz after leaving the insulation layer at 85° C. and 85% relative humidity for 240 hours.

4. The flexible metal laminate according to claim 1, wherein a thickness of the polyimide film is 10 to 100 ρ m.

5. The flexible metal laminate according to claim 1, wherein the first and second liquid crystal polymer coating layers are formed by coating a liquid crystal polymer composition on the polyimide film, drying at a temperature of 200° C. or less, and post-baking at a temperature of 250 to 300° C.

6. The flexible metal laminate according to claim 1, wherein a thickness of each of the first and second liquid crystal polymer coating layers is 0.1 to 10 λm.

7. The flexible metal laminate according to claim 1, wherein the metal layer comprises copper.

8. The flexible metal laminate according to claim 1, wherein a thickness of the metal layer is 1 to 20 μm.

9. A printed circuit board using the flexible metal laminate according to claim 1.

10. A printed circuit board using the flexible metal laminate according to claim 2.

11. A printed circuit board using the flexible metal laminate according to claim 3.

12. A printed circuit board using the flexible metal laminate according to claim 4.

13. A printed circuit board using the flexible metal laminate according to claim 5.

14. A printed circuit board using the flexible metal laminate according to claim 6.

15. A printed circuit board using the flexible metal laminate according to claim 7.

16. A printed circuit board using the flexible metal laminate according to claim 8.
